(19) United States
(12) Patent Application Publication
(10) Pub. No.: US 2020/0024735 A1
(43) Pub. Date: Jan. 23, 2020

(54) EROSION RESISTANT METAL FLUORIDE COATINGS DEPOSITED BY ATOMIC LAYER DEPOSITION

(71) Applicant: Applied Materials, Inc., Santa Clara, CA (US)

(72) Inventors: Xiaowei Wu, San Jose, CA (US); Jennifer Y. Sun, Mountain View, CA (US); Michael R. Rice, Pleasanton, CA (US)

(21) Appl. No.: 16/204,655

(22) Filed: Nov. 29, 2018

Related U.S. Application Data
(60) Provisional application No. 62/700,063, filed on Jul. 18, 2018.

(51) Int. Cl. C23C 16/455; C23C 16/30

(52) U.S. Cl. CPC C23C 16/45527; C23C 16/30

(57) ABSTRACT

Embodiments of the present disclosure relate to articles, coated articles and methods of coating such articles with a rare earth metal containing fluoride coating. The coating can contain at least a first metal (e.g., a rare earth metal, tantalum, zirconium, etc.) and a second metal that have been co-deposited onto a surface of the article. The coating can include a homogenous mixture of the first metal and the second metal and does not contain mechanical segregation between layers in the coating.

### TECHNICAL FIELD

Embodiments of the present disclosure relate to erosion resistant metal fluoride coatings, coated articles and methods of forming such coatings using atomic layer deposition.

### BACKGROUND

In the semiconductor industry, devices are fabricated by a number of manufacturing processes producing structures of an ever-decreasing size. Some manufacturing processes, such as plasma etch and plasma clean processes, expose a substrate to a high-speed stream of plasma to etch or clean the substrate. The plasma may be highly corrosive, and may corrode processing chambers and other surfaces and components that are exposed to the plasma. This corrosion may generate particles, which frequently contaminate the substrate that is being processed, contributing to device defects. Fluorine containing plasmas, which can include fluoride ions and radicals, can be particularly harsh resulting in particles generated from interaction of the plasma with materials within the processing chamber. The plasmas can damage protective coatings and underlying materials of chamber components; they can cause surface deterioration of the protective coatings and increased risk of cracking and delamination. Radical recombination rate drift resulting from slow fluorination of the chamber surface can also cause wafer process drift.

As device geometries shrink, susceptibility to defects increases, and particle contaminant requirements (i.e., on-wafer performance) become more stringent. To minimize particle contamination introduced by plasma etch and/or plasma clean processes, chamber materials have been developed that are resistant to plasmas. Examples of such plasma resistant materials include ceramics composed of Al₂O₃, AlN, SiC, Y₂O₃, quartz, and ZrO₂. Different ceramics provide different material properties, such as plasma resistance, rigidity, flexural strength, thermal shock resistance, and so on. Also, different ceramics have different material costs. Accordingly, some ceramics have superior plasma resistance, other ceramics have lower costs, and still other ceramics have superior flexural strength and/or thermal shock resistance.

Plasma spray coatings formed of Al₂O₃, AlN, SiC, Y₂O₃, quartz, and ZrO₂ can reduce particle generation from chamber components, but such plasma spray coatings are unable to penetrate into and coat high aspect ratio features such as holes of a showerhead. While some deposition techniques are able to coat high aspect ratio features, the resulting coatings may erode and form particles in certain plasma environments, for example, fluorine containing plasmas, or suffer from mechanical segregation of layers of materials due to insufficient inter-diffusion in the coatings.

### SUMMARY

Embodiments described herein are directed to an article comprising: a body; and a rare earth metal containing fluoride coating on a surface of the body, wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, zirconium, hafnium, aluminum and tantalum, wherein the first metal is different from the second metal, and wherein the rare earth metal containing fluoride coating comprises a homogenous mixture of the first metal and the second metal.

Further embodiments are directed to a method comprising: co-depositing a rare earth metal containing fluoride coating on a surface of an article using atomic layer deposition, wherein co-depositing the rare earth metal containing fluoride coating comprises: contacting the surface with a first precursor for a first duration to form a partial metal adsorption layer comprising a first metal (M1), wherein the first precursor is selected from a group consisting of a rare earth metal containing precursor, a zirconium containing precursor, a hafnium containing precursor, an aluminum containing precursor and a tantalum containing precursor; contacting the partial metal adsorption layer with a second precursor different from the first precursor for a second duration to form a co-adsorption layer comprising the first metal (M1) and a second metal (M2), wherein the second metal precursor is selected from a group consisting of a rare earth metal containing precursor, a zirconium containing precursor, a hafnium containing precursor, an aluminum containing precursor and a tantalum containing precursor, wherein the first metal is different from the second metal; and contacting the co-adsorption layer with a reactant to form the rare earth metal containing fluoride coating, wherein the rare earth metal containing fluoride coating comprises about 1 mol % to about 40 mol % of the first metal and about 1 mol % to about 40 mol % of the second metal, and wherein the rare earth metal containing fluoride coating comprises a homogenous mixture of the first metal and the second metal.

According to embodiments, also described is a method comprising: co-depositing a rare earth metal containing fluoride coating on a surface of an article using atomic layer deposition, wherein co-depositing the rare earth metal containing fluoride-coating comprises: performing at least one co-dosing cycle comprising: contacting the surface with a mixture of a first precursor and a second precursor for a first duration to form a co-adsorption layer, wherein the first precursor and the second precursor are each selected from a group consisting of a rare earth metal containing precursor, a zirconium containing precursor, a hafnium containing precursor, an aluminum containing precursor and a tantalum containing precursor; and contacting the co-adsorption layer with a fluorine containing reactant to form the rare earth metal containing fluoride coating, wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, zirconium, hafnium, aluminum and tantalum, wherein the first metal is different from the second metal, and wherein the rare earth metal containing fluoride coating comprises a homogenous mixture of the first metal and the second metal.

According to embodiments, also described herein is a method comprising: depositing a rare earth metal containing fluoride coating on a surface of an article using atomic layer deposition, wherein depositing the rare earth metal containing fluoride coating comprises: contacting the surface with a first precursor for a first duration to form a first metal adsorption layer; contacting the first metal adsorption layer with a fluorine containing reactant to form a first metal fluoride layer, contacting the first metal fluoride layer with a second precursor for a second duration to form a second metal adsorption layer; contacting the second metal adsorption layer with the fluorine containing reactant or an additional fluorine containing reactant to form a second metal fluoride layer, forming the rare earth metal containing fluoride coating from the first metal fluoride layer and the second metal fluoride layer, wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, zirconium, hafnium and tantalum, wherein the first metal is different from the second metal.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of a processing chamber.

FIG. 2A depicts one embodiment of a co-deposition process in accordance with an atomic layer deposition technique as described herein.

FIG. 2B depicts another embodiment of a co-deposition process in accordance with an atomic layer deposition technique as described herein.

FIG. 2C depicts another embodiment of a co-deposition process in accordance with an atomic layer deposition technique as described herein.

FIG. 2D depicts another embodiment of a co-deposition process in accordance with an atomic layer deposition technique as described herein.

FIG. 3A illustrates a method for forming a rare earth metal containing fluoride coating using atomic layer deposition as described herein.

FIG. 3B illustrates a method for forming a rare earth metal containing fluoride coating using atomic layer deposition as described herein.

FIG. 3C illustrates a method for forming a rare earth metal containing fluoride coating using atomic layer deposition as described herein.

FIG. 3D illustrates a method for forming a rare earth metal containing fluoride coating using atomic layer deposition as described herein.

### DETAILED DESCRIPTION

Embodiments described herein relate to complex metal containing fluoride coatings that include a mixture of multiple metals. Embodiments also relate to coated articles and methods of forming such complex metal containing fluoride coatings using atomic layer deposition. The complex metal containing fluoride coatings may include a first metal (M1) and a second metal (M2) where the first metal and the second metal are independently selected from a rare earth metal (RE), zirconium, tantalum, hafnium and aluminum, and where the first metal is different from the second metal. In certain embodiments, the rare earth metal containing fluoride coating may include more than two metals, for example, M1, M2, M3, M4, etc. each of which is independently selected from a rare earth metal, zirconium, tantalum, hafnium and aluminum. For example, the rare earth metal containing fluoride coatings may be in the form of M1ₓM2_{y}F_{z} (e.g., YₓZr_{y}F_{z}, YₓEr_{y}F_{z}, YxTayFz, etc.), M1_{w}M2ₓM3_{y}F_{z} (e.g., Y_{w}ErₓF_{z}, Y_{w}ZrₓHf_{y}F_{z}, etc.), M1ᵥM2_{w}M3ₓM4_{y}F_{z} (e.g., YᵥEr_{w}ZrₓHf_{y}F_{z}), and/or more complex metal fluoride coatings with a larger number of mixed metals. As will be discussed in more detail below, the multiple different metals (e.g., the first metal, the second metal, etc.) may be co-deposited onto an article using a non-line of sight technique such as atomic layer deposition (ALD). Alternatively, multiple different metal fluorides may be sequentially deposited and then interdiffuse to form the complex metal fluoride coating. The coatings are resistant to plasma chemistries used for semiconductor processing, for example, bromine containing plasmas having bromine ions and bromine radicals. Without being bound by any particular theory, it is believed that incorporating a second metal (M2) or a third, fourth etc. (i.e. M3, M4, etc.) into the coating reduces vacancies in the material, which thereby reduces diffusion of fluorine (e.g., from a CF₄ plasma) into the coating.

According to embodiments described herein, the coatings may be formed of multiple metals (e.g., RE_{w}M_{y}F_{z}, YₓZr_{y}F_{z} or RE_{w}YₓZr_{y}F_{z}) co-deposited in a single adsorption layer. In some embodiments at least one of the metals is a rare earth metal. The at least one rare earth metal may be selected from yttrium, erbium, lanthanum, lutetium, scandium, gadolinium, samarium or dysprosium. In certain embodiments, the coatings may be formed of tantalum and at least one additional metal. The at least one additional metal may be selected from a rare earth metal (RE), zirconium (Zr), aluminum (Al), hafnium (Hf), silicon (Si) and hafnium (Hf) in embodiments. According to embodiments, the complex metal containing fluoride coating can contain about 1 mol % to about 40 mol %, or about 5 mol % to about 30 mol %, or about 10 mol % to about 20 mol % of the first metal and about 1 mol % to about 40 mol %, or about 5 mol % to about 30 mol %, or about 10 mol % to about 20 mol % of the second metal.

In certain embodiments, the coatings may be formed of at least one rare earth metal (e.g., as the first metal) and at least one additional (e.g., second) metal (e.g., RE_{w}M_{y}F_{z}, YₓZr_{y}F_{z} or RE_{w}YₓZr_{y}F_{z}) co-deposited in a single adsorption layer. The at least one rare earth metal may be selected from yttrium, erbium, lanthanum, lutetium, scandium, gadolinium, samarium or dysprosium. Alternatively, the coatings may be formed of tantalum and at least one additional metal. The at least one additional metal may be selected from a rare earth metal (RE), zirconium (Zr), aluminum (Al), hafnium (Hf) and silicon (Si) in embodiments. According to embodiments, the rare earth metal containing fluoride coating can contain about 5 mol % to about 30 mol %, or about 10 mol % to about 25 mol %, or about 15 mol % to about 20 mol % of at least one rare earth metal and about 1 mol % to about 40 mol %, or about 5 mol % to about 30 mol %, or about 10 mol % to about 20 mol % of at least one additional metal.

The coatings provide resistance to erosion by plasmas (e.g., fluorine containing plasmas) used for semiconductor processing and chamber cleaning. Therefore, the coatings provide good particle performance and process stability performance during such processing and cleaning procedures. As used herein, the terms “erosion resistant coating” or “plasma resistant coating” refer to a coating having a particularly low erosion rate when exposed to particular plasmas, chemistry and radicals (e.g., fluorine-based plasma, chemistry and/or radicals, chlorine-based plasma, chemistry and/or radicals, etc.). The co-deposition scheme results in a coating that eliminates surface fluorination that can lead to wafer process drift, achieves a much more uniform coating at the angstrom scale and improves phase control (e.g., lack of inter-diffusion that leaves YF₃ and other metal phases in the coating). According to embodiments, the co-deposition scheme results in a coating having a homogenous mixture of the metals and, without being bound to any particular theory, it is believed may eliminate vacancies within the co-deposited coating (as compared to an oxide coating) thereby preventing fluorine to diffuse into the coating. For example, a coating comprising a mixture of Y₂O₃ and ZrO₂ as deposited by a deposition technique other than ALD or deposited by ALD using a sequential deposition technique may include one or more segregated phases at some locations. This may result in some vacancies for the Y₂O₃ phase, which may increase a susceptibility to fluorination. In contrast, ALD deposition of YₓZr_{y}F_{z} (e.g., a YF—ZrF solid solution) using a co-deposition technique and/or a co-dosing technique may reduce or eliminate phase segregation and result in a homogenous mixture of Y and Zr. The co-deposition scheme also provides the flexibility of adjusting the ratio of deposited metals, for example, by adjusting the number of pulses and/or the pulsing time, temperature, pressure, etc. This flexibility enables the formation of coatings having particular mole ratios of two or more metals.

In embodiments, the complex metal fluoride coating may include a two metal composition (M1ₓM2_{y}F_{z}), a three metal composition (M1_{w}M2ₓM3_{y}F_{z}), a four metal composition (M1ᵥM2_{w}M3ₓM4_{y}F_{z}), a five metal composition (M1ᵤM2ᵥM3_{w}M4ₓM5_{y}F_{z}), a six metal composition (M1ₜM2ᵤM3ᵥM4_{w}M5ₓM6_{y}F_{z}), and so on. In each of the complex metal fluoride coatings, the variables t, u, v, w, x, y, z may be positive integers or decimal values. Some example values of t, u, v, w, x, y, z may range from about 0.1 to about 10. In some embodiments the complex metal fluoride coating is a rare earth metal containing fluoride coating. In embodiments, the rare earth metal containing fluoride coating is selected from YₓZr_{y}F_{z}, ErₓZr_{y}F_{z}, Y_{w}ErₓZr_{y}F_{z}, Y_{w}ErₓHf_{y}F_{z}, Y_{w}ZrₓHf_{y}F_{z}, Er_{w}ZrₓHf_{y}F_{z}, YᵥEr_{w}ZrₓHf_{y}F_{z}, YₓHf_{y}F_{z}, ErₓHf_{y}F_{z}, YₓTa_{y}F_{z}, ErₓTa_{y}F_{z}, Y_{w}ErₓTa_{y}F_{z}, Y_{w}TaₓZr_{y}F_{z}, Y_{w}TaₓHf_{y}F_{z}, Er_{w}TaₓZr_{y}F_{z} Er_{w}TaₓHf_{y}F_{z} and YᵥEr_{w}TaₓHf_{y}F_{z}. In one embodiment, the rare earth metal containing fluoride coating includes YZrF having an atomic ratio of yttrium to zirconium of about 3. In another embodiment, the rare earth metal containing fluoride coating includes YZrOF and has an atomic ratio of yttrium to zirconium of about 4.6. In further embodiments, the rare earth metal containing fluoride coating may include a composition selected from La_{w}YₓZr_{y}F_{z}, Lu_{w}YₓZr_{y}F_{z}, Sc_{w}YₓZr_{y}F_{z}, Gd_{w}YₓZr_{y}F_{z}, Sm_{w}YₓZr_{y}F_{z}, Dy_{w}YₓZr_{y}F_{z}, La_{w}YₓZr_{y}F_{z}, Lu_{w}YₓTa_{y}F_{z}, Sc_{w}YₓTa_{y}F_{z}, Gd_{w}YₓTa_{y}F_{z}, Sm_{w}YₓTa_{y}F_{z}, Dy_{w}YₓTa_{y}F_{z}, Er_{w}YₓHf_{y}F_{z}, La_{w}YₓHf_{y}F_{z}, Lu_{w}YₓHf_{y}F_{z}, Sc_{w}YₓHf_{y}F_{z}, Gd_{w}YₓHf_{y}F_{z}, Sm_{w}YₓHf_{y}F_{z}, Dy_{w}YₓHf_{y}F_{z}. In some embodiments, the coatings may contain RE_{w}ZrₓAl_{y}F_{z}, for example, Y_{w}ZrₓAl_{y}F_{z}. Other complex fluorides may also be used.

Examples of yttrium-containing fluoride compounds of which the plasma resistant coating may be formed include YF, YₓAl_{y}F_{z}, YₓZr_{y}F_{z}, YₓHf_{y}F_{z}, YₐZrₓAl_{y}F_{z}, YₐZrₓHf_{y}F_{z}, YₐHfₓAl_{y}F_{z}, YᵥZr_{w}HfₓAl_{y}F_{z}, or YₓEr_{y}F_{z}. The yttrium content in the coating may range from about 0.1 mol % to close to 100 mol %. For yttrium-containing fluorides, the yttrium content may range from about 0.1 mol % to close to 100 mol % and the fluorine content may range from about 0.1 mol % to close to 100 mol %.

Examples of erbium-containing fluoride compounds that the plasma resistant coating may be formed of include Er₂O₃, ErₓAl_{y}F_{z} (e.g., Er₃Al₅F₁₂), ErₓZr_{y}F_{z}, ErₓHf_{y}F_{z}, ErₐZrₓAl_{y}F_{z}, ErₐZrₓHf_{y}F_{z}, ErₐHfₓAl_{y}F_{z}, YₓEr_{y}F_{z}, and ErₐYₓZr_{y}F_{z} (e.g., a single phase solid solution of Y₂O₃, ZrO₂ and Er₂O₃). The erbium content in the plasma resistant coating may range from about 0.1 mol % to close to 100 mol %. For erbium-containing fluorides, the erbium content may range from about 0.1 mol % to close to 100 mol % and the fluorine content may range from about 0.1 mol % to close to 100 mol %.

Advantageously, Y₂O₃ and Er₂O₃ are miscible. A single phase solid solution can be formed for any combination of Y₂O₃ and Er₂O₃. For example, a mixture of just over 0 mol % Er₂O₃ and just under 100 mol % Y₂O₃ may be combined and co-deposited to form a plasma resistant coating that is a single phase solid solution. Additionally, a mixture of just over 0 mol % E₂O₃ and just under 100 mol % Y₂O₃ may be combined to form a plasma resistant coating that is a single phase solid solution. Plasma resistant coatings of YₓEr_{y}F_{z} may contain between over 0 mol % to under 100 mol % YF₃ and over 0 mol % to under 100 mol % ErF₃. Some notable examples include 90-99 mol % YF₃ and 1-10 mol % ErF₃, 80-89 mol % YF₃ and 11-20 mol % Er₂O₃, 70-79 mol % YF₃ and 21-30 mol % ErF₃, 60-69 mol % YF₃ and 31-40 mol % ErF₃, 50-59 mol % YF₃ and 41-50 mol % ErF₃, 40-49 mol % YF₃ and 51-60 mol % ErF₃, 30-39 mol % YF₃ and 61-70 mol % ErF₃, 20-29 mol % YF₃ and 71-80 mol % ErF₃, 10-19 mol % Y₂O₃ and 81-90 mol % ErF₃, and 1-10 mol % YF₃ and 90-99 mol % ErF₃. The single phase solid solution of YₓEr_{y}F_{z} may have a monoclinic cubic state at temperatures below about 2330° C.

Advantageously, ZrO₂ may be combined with YF₃ and ErF₃ to form a single phase solid solution containing a mixture of zirconium, YF₃ and ErF₃ (e.g., ErₐYₓZr_{y}F_{z}). The solid solution of YₐErₓZr_{y}F_{z} may have a cubic, hexagonal, tetragonal and/or cubic fluorite structure. The solid solution of YₐErₓZr_{y}F_{z} may contain over 0 mol % to 60 mol % Zr, over 0 mol % to 99 mol % ErF₃, and over 0 mol % to 99 mol % YF₃. Some notable amounts of ZrO₂ that may be used include 2 mol %, 5 mol %, 10 mol %, 15 mol %, 20 mol %, 30 mol %, 50 mol % and 60 mol %. Some notable amounts of ErF₃ and/or YF₃ that may be used include 10 mol %, 20 mol %, 30 mol %, 40 mol %, 50 mol %, 60 mol %, 70 mol %, 80 mol %, and 90 mol %.

Plasma resistant coatings of YₐZrₓAl_{y}F_{z} may contain over 0% to 60 mol % Zr, over 0 mol % to 99 mol % YF₃, and over 0 mol % to 60 mol % Al. Some notable amounts of ZrO₂ that may be used include 2 mol %, 5 mol %, 10 mol %, 15 mol %, 20 mol %, 30 mol %, 50 mol % and 60 mol %. Some notable amounts of YF₃ that may be used include 10 mol %, 20 mol %, 30 mol %, 40 mol %, 50 mol %, 60 mol %, 70 mol %, 80 mol %, and 90 mol %. Some notable amounts of Al₂O₃ that may be used include 2 mol %, 5 mol %, 10 mol %, 20 mol %, 30 mol %, 40 mol %, 50 mol % and 60 mol %. In one example, the plasma resistant coating of YₐZrₓAl_{y}F_{z} contains 42 mol % YF₃, 40 mol % Zr and 18 mol % Al and has a lamellar structure. In another example, the plasma resistant coating of YₐZrₓAl_{y}F_{z} contains 63 mol % YF₃, 10 mol % Zr and 27 mol % ErF₃ and has a lamellar structure.

In embodiments, the rare earth metal containing fluoride coating contains about 1 mol % to about 40 mol % of a first metal (e.g., a rare earth metal such as Y, Er, etc., or tantalum) and about 1 mol % to about 40 mol % of a second metal (e.g., a rare earth metal, Zr, Hf, Ta, Al, Si). In further embodiments, the complex metal fluoride coating contains about 1 mol % to about 40 mol %, or about 5 mol % to about 30 mol % of Ta and about 1 mol % to about 40 mol %, or about 1 mol % to about 20 mol % of the second metal (e.g., RE, Zr, Hf, Al, Si). In embodiments, the complex metal fluoride coating contains about 1 mol % to about 40 mol %, or about 5 mol % to about 30 mol % yttrium and about 1 mol % to about 40 mol %, or about 1 mol % to about 20 mol % zirconium, hafnium or tantalum, or about 10 mol % to about 25 mol % yttrium and about 5 mol % to about 17 mol % Zr, Hf or Ta, or about 15 mol % to about 21.5 mol % yttrium and about 10 mol % to about 14.5 mol % Zr, Hf or Ta. In embodiments, the coating contains a mixture of Y and Er, where the combined mol % of the Y and Er is about 5 mol % to about 30 mol % (e.g., may contain 1-29 mol % Y and 1-29 mol % Er). The coating may additionally contain about 1 mol % to about 20 mol % zirconium, hafnium or tantalum.

In embodiments, the thickness of the complex metal fluoride coating or rare earth metal containing fluoride coating may be about 5 nm to about 10 μm, or about 5 nm to about 5 μm, or about 25 nm to about 5 μm, or about 50 nm to about 500 nm, or about 75 nm to about 200 nm. In some embodiments, the thickness of the complex metal fluoride coating or the rare earth metal containing fluoride coating may be about 50 nm, or about 75 nm, or about 100 nm, or about 125 nm, or about 150 nm. The complex metal fluoride coating or the rare earth metal containing fluoride coating may conformally cover one or more surfaces of a body of an article (including high aspect ratio features such as gas holes) with a substantially uniform thickness. In one embodiment, the rare earth metal containing fluoride coating has a conformal coverage of the underlying surface that is coated (including coated surface features) with a uniform thickness having a thickness variation of less than about +/−20%, a thickness variation of +/−10%, a thickness variation of +/−5%, or a lower thickness variation.

In further embodiments, the complex metal fluoride coating or the rare earth metal containing fluoride coating does not contain separate layers containing a fluoride of the first metal and a fluoride of the second metal (or the third metal, fourth metal, etc.). In particular, in certain embodiments, the complex metal fluoride coating or the rare earth metal containing fluoride coating may not be formed by sequential atomic layer deposition cycles of the multiple metals. Rather, the first metal and the second metal, for example, may be co-deposited onto the article or the body of the article in embodiments. Consequently, the rare earth metal containing fluoride coating may be free of mechanical segregation between a layer containing the first metal and a layer containing the second additional metal. As a further result of the co-deposition process, the complex metal fluoride coating or rare earth metal containing fluoride coating may contain a homogenous mixture of the first metal (e.g., a rare earth metal) and the second metal without performing annealing and also may not comprise a concentration gradient of the first metal or the second metal resulting from incomplete inter-diffusion of the materials in the coating.

In alternative embodiments, a sequential atomic layer deposition (ALD) process is performed. For the sequential ALD process a first metal precursor may be adsorbed onto a surface, and a fluorine-based reactant may react with the adsorbed first metal (e.g., a rare earth metal, tantalum, etc.) to form a first metal fluoride layer. Subsequently a second metal precursor may be adsorbed onto the first metal fluoride layer, and an fluorine-based reactant may react with the adsorbed second metal to form a second metal (e.g., zirconium, aluminum, hafnium, tantalum, silicon, etc.) fluoride layer. The metals from the first and second metal fluoride layers may then interdiffuse into one another. When a coating is deposited using sequential deposition cycles of a first metal and a second metal, annealing may be performed to affect inter-diffusion between the layers. Such annealing can result in a concentration gradient of the phases of the metals (e.g., YF₃ and ZrO₂ to YZrF) from the surface toward the underlying article, and such coatings lack homogeneity throughout. The coatings described herein by co-deposition form homogenous mixtures of the first metal and the second metal. No annealing is generally performed to implement inter-diffusion.

According to embodiments, the complex metal fluoride coating or rare earth metal containing fluoride coating may be formed of a multilayer stack having alternating layers of material. In one embodiment, a buffer layer may be deposited on the surface of the article or a body of the article, and the complex metal fluoride coating or rare earth metal containing fluoride coating may be deposited on the buffer layer. The buffer layer may include, but is not limited to, an aluminum oxide (e.g., Al₂O₃), a silicon oxide (e.g., SiO₂), aluminum nitride or combinations thereof. In other embodiments, a first metal (e.g., yttrium, erbium, tantalum, etc.) and a second metal (e.g., a rare earth metal, zirconium, aluminum, hafnium, tantalum, etc.) may be co-deposited onto the article (or onto the buffer layer, if used) using ALD to form a first co-deposition layer. A second layer of material (e.g., a metal fluoride, a rare earth metal fluoride, a co-deposited rare earth metal zirconium oxide, and so on) may be deposited or co-deposited on the first co-deposition layer. Each deposition or co-deposition cycle can be repeated as many times as desired to achieve a target composition and/or thickness of the final multilayer coating.

The thickness of each layer in the multilayer complex metal fluoride coating or rare earth metal containing fluoride coating may be from about 10 nm to about 1.5 μm. In embodiments, the buffer layer (e.g., amorphous Al₂O₃) may have a thickness of about 1.0 μm and the rare earth metal containing fluoride layer may have a thickness of about 50 nm. A ratio of the complex metal fluoride or rare earth metal containing fluoride layer thickness to the buffer layer thickness may be 200:1 to 1:200, or about 100:1 to 1:100, or about 50:1 to about 1:50. The thickness ratio may be selected in accordance with specific chamber applications.

The complex metal fluoride or rare earth metal containing fluoride coating may be grown or co-deposited using ALD with precursors for co-deposition of a first metal containing fluoride layer containing tantalum and/or at least one rare earth metal (e.g., yttrium, erbium, etc.) and a second metal (e.g., RE, Zr, Ta, Hf, Al, Si). In one embodiment, the complex metal fluoride coating or rare earth metal containing fluoride layer has a polycrystalline structure.

The buffer layer may include amorphous aluminum oxide or similar material. The buffer layer provides robust mechanical properties and may enhance dielectric strength, provide better adhesion of the complex metal fluoride or rare earth metal containing fluoride coating to the component (e.g., formed of Al 6061, Al 6063 or ceramic), and prevent cracking of the complex metal fluoride or rare earth metal containing fluoride coating at temperatures up to about 350° C., or up to about 300° C., or up to about 250° C., or up to about 200° C., or from about 200° C. to about 350° C., or from about 250° C. to about 300° C. Such metal articles have a coefficient of thermal expansion that may be significantly higher than the coefficient of thermal expansion of a complex metal fluoride coating or a rare earth metal containing fluoride coating. By first applying the buffer layer 209, the detrimental effect of mismatch in coefficients of thermal expansion between the article and the complex metal containing fluoride coating may be managed. Since ALD is used for the deposition, the internal surfaces of high aspect ratio features such as gas delivery holes in a showerhead or a gas delivery line may be coated, and thus, an entirety of a component may be protected from exposure to a corrosive environment. In some embodiments, the buffer layer may include a material that has a thermal expansion coefficient between the value of the article's thermal expansion coefficient and the value of the complex metal containing fluoride coating thermal expansion coefficient. Additionally, the buffer layer may act as a barrier that prevents migration of metal contaminants (e.g., Mg, Cu, etc. trace metals) from the component or article into the complex metal containing fluoride coating. The addition of the amorphous Al₂O₃ layer as a buffer layer under the complex metal fluoride coating may increase the thermal resistance of the complex metal fluoride coating as a whole by relieving the elevated stress concentrated at some areas of the complex metal fluoride/Al 6061 interface.

Also described herein are articles having a complex metal fluoride coating or rare earth metal containing fluoride coating as described above. In embodiments, the article may be any type of component for use in a semiconductor processing chamber including, but not limited to, an electrostatic chuck, a gas delivery plate, a chamber wall, a chamber liner, a door, a ring, a showerhead, a nozzle, a plasma generation unit, a radiofrequency electrode, an electrode housing, a diffuser an a gas line. The article may contain a material including, but not limited to, aluminum (Al), silicon (Si), copper (Cu) and magnesium (Mg). In embodiments, the article may contain a ceramic material including, but not limited to, an aluminum oxide (AlₓO_{y}), a silicon oxide (SiₓO_{y}), aluminum nitride (AlN) or silicon carbide (SiC) material. In some embodiments, the article or a body of an article may be an aluminum Al 6061, Al 6063 material. In some embodiments, the surface of the article or the body of the article has a surface roughness of about 120 μin to about 180 μin, or about 130 μin to about 170 μin, or about 140 μin to about 160 μin.

The complex metal coating may be very dense with a porosity of about 0% (e.g., the rare earth metal containing fluoride coating may be porosity-free in embodiments). The complex metal fluoride coatings may be resistant to corrosion and erosion from plasma etch chemistries, such as CCl₄/CHF₃ plasma etch chemistries, HCl₃Si etch chemistries, NF₃ containing etch chemistries. Additionally, the complex metal fluoride coatings described herein having the buffer layer may be resistant to cracking and delamination at temperatures up to about 350° C. For example, a chamber component having the rare earth metal containing fluoride coating and buffer layer described herein may be used in processes that include heating to temperatures of about 200° C. The chamber component may be thermally cycled between room temperature and the temperature of about 200° C. without introducing any cracks or delamination in the rare earth metal containing fluoride coating.

In some embodiments, the article or the body of the article may include at least one feature (e.g., a gas hole), wherein the feature has an aspect ratio of length to diameter (L:D) of about 5:1 to about 300:1, or about 10:1 to about 200:1, or about 20:1 to about 100:1, or about 5:1 to about 50:1, or about 7:1 to about 25:1, or about 10:1 to about 20:1. The complex metal fluoride coating or rare earth metal containing fluoride coating may conformally cover the body of the article and a surface of the feature. In some embodiments, the article or the body of the article may include a feature (e.g., a channel) having an aspect ratio of depth to width (D:W) of ab about 5:1 to about 300:1, or about 10:1 to about 200:1, or about 20:1 to about 100:1, or about 5:1 to about 50:1, or about 7:1 to about 25:1, or about 10:1 to about 20:1. The complex metal fluoride coating or rare earth metal containing fluoride coating may conformally cover the body of the article and a surface of the feature.

In various embodiments, high aspect ratio features of the articles (as described above) may be effectively coated with complex metal fluoride coatings or rare earth metal containing fluoride coatings described herein. The complex metal fluoride coatings may have a single phase, two phases, or more than two phases. The complex metal fluoride coatings or rare earth metal containing fluoride coatings are conformal within the high aspect ratio features with a substantially uniform thickness as described above.

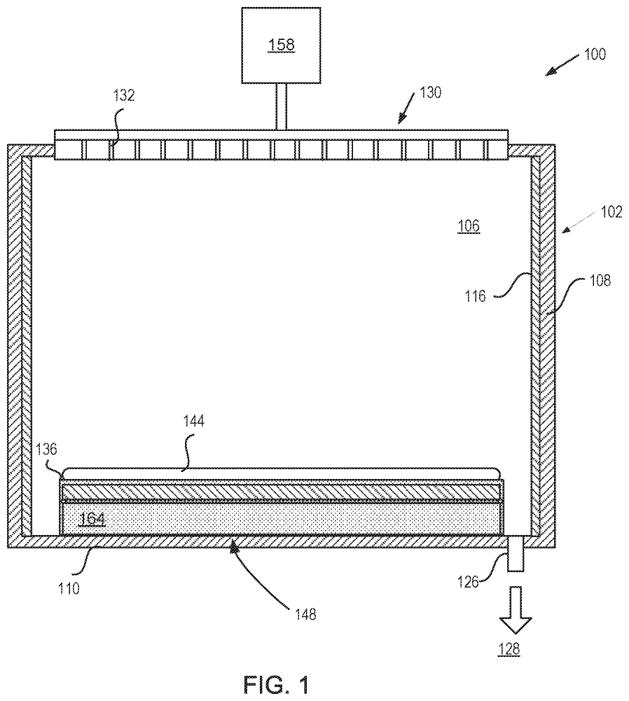

FIG. 1 is a sectional view of a semiconductor processing chamber 100 having one or more chamber components that are coated with a complex metal fluoride or rare earth metal containing fluoride coating in accordance with embodiments described herein. The base materials of at least some components of the chamber may include one or more of Al, for example, AlₓO_{y}, AlN, Al 6061, or Al 6063, Si, for example, SiₓO_{y}, SiO₂, or SiC, copper (Cu), magnesium (Mg), titanium (Ti) and stainless steel (SST). The processing chamber 100 may be used for processes in which a corrosive plasma environment (e.g., a fluorine containing plasma) having plasma processing conditions is provided. For example, the processing chamber 100 may be a chamber for a plasma etcher or plasma etch reactor, a plasma cleaner, plasma enhanced CVD or ALD reactors and so forth. Examples of chamber components that may include the complex metal fluoride coating or rare earth metal containing fluoride coating include chamber components with complex shapes and features having high aspect ratios as described above. Some exemplary chamber components include a substrate support assembly, an electrostatic chuck, a ring (e.g., a process kit ring or single ring), a chamber wall, a base, a gas distribution plate, a showerhead, gas lines, a nozzle, a lid, a liner, a liner kit, a shield, a plasma screen, a flow equalizer, a cooling base, a chamber viewport, a chamber lid, and so on.

In one embodiment, the processing chamber 100 includes a chamber body 102 and a showerhead 130 that enclose an interior volume 106. The showerhead 130 may include a showerhead base and a showerhead gas distribution plate. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110. An outer liner 116 may be disposed adjacent the sidewalls 108 to protect the chamber body 102. Any of the showerhead 130 (or lid and/or nozzle), sidewalls 108 and/or bottom 110 may include the rare earth metal containing fluoride coating.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewall 108 of the chamber body 102. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or cleaning gases to the interior volume 106 through the showerhead 130 or lid and nozzle. Showerhead 130 may be used for processing chambers used for dielectric etch (etching of dielectric materials). The showerhead 130 may include a gas distribution plate (GDP) having multiple gas delivery holes 132 throughout the GDP. The showerhead 130 may include the GDP bonded to an aluminum base or an anodized aluminum base. The GDP may be made from Si or SiC, or may be a ceramic such as Y₂O₃, Al₂O₃, Y₃Al₅O₁₂ (YAG), and so forth.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier and purge gases include N₂, He, Ar, and other gases inert to process gases (e.g., non-reactive gases).

A substrate support assembly 148 is disposed in the interior volume 106 of the processing chamber 100 below the showerhead 130 or lid. The substrate support assembly 148 includes a support 136 that holds the substrate 144 during processing. The support 136 is attached to the end of a shaft (not shown) that is coupled to the chamber body 102 via a flange 164. The substrate support assembly 148 may include, for example, a heater, an electrostatic chuck, a susceptor, a vacuum chuck, or other substrate support assembly component.

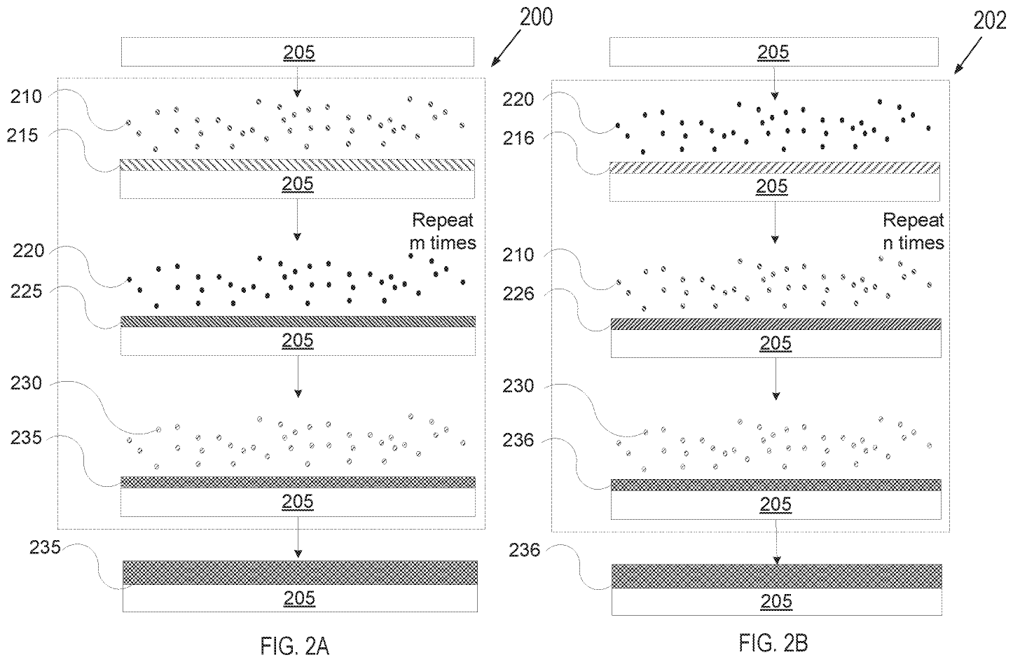

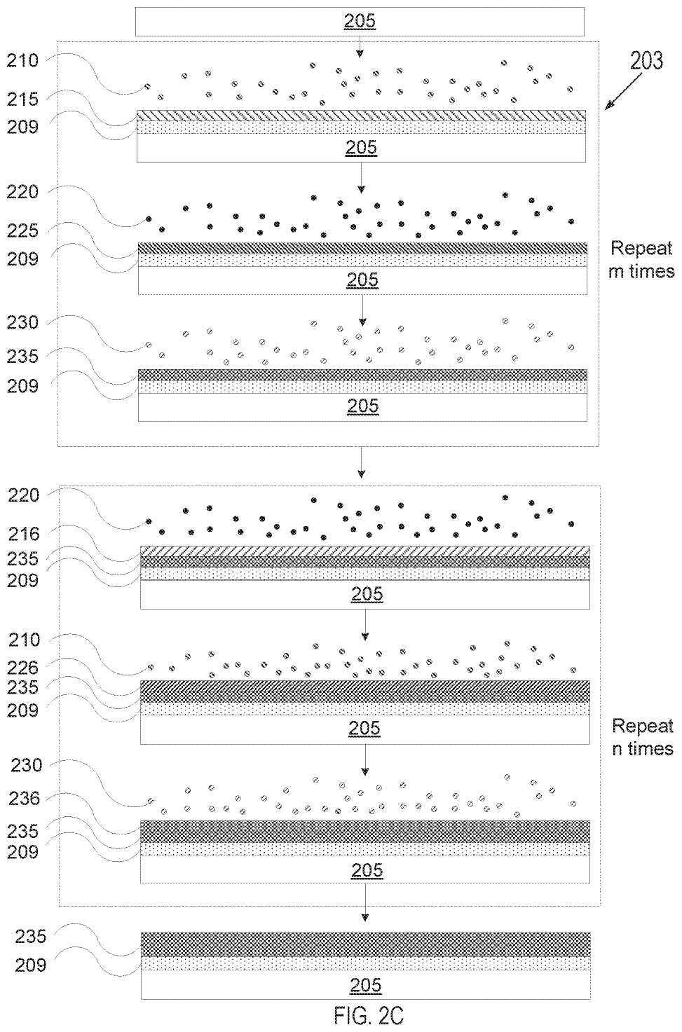

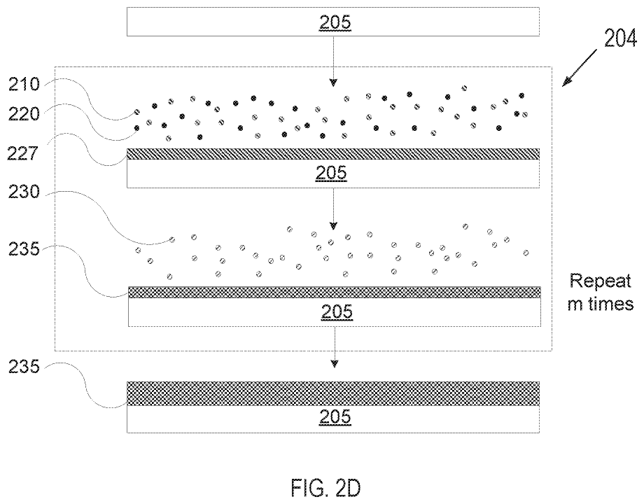

FIG. 2A depicts an embodiment of a co-deposition process 200 in accordance with an ALD technique to grow or deposit a first metal-rich fluoride coating on an article. FIG. 2B depicts another embodiment of a co-deposition process in accordance with an ALD technique as described herein to grow or deposit a second metal-rich rare earth metal fluoride coating on an article. FIG. 2C depicts another embodiment of a co-deposition process in accordance with an ALD technique as described herein. FIG. 2D depicts another embodiment of a co-deposition process that utilizes co-dosing of the rare earth metal and other metal in accordance with an ALD technique as described herein.

For ALD co-deposition processes, either adsorption of at least two precursors onto a surface or a reaction of a reactant with the adsorbed precursors may be referred to as a “half-reaction.” During a first half reaction, a first precursor (or a mixture of precursors) may be pulsed onto a surface of the article 205 for a period of time sufficient to allow the precursor to partially (or fully) adsorb onto the surface. The adsorption is self-limiting as the precursor will adsorb onto a number of available sites on the surface, forming a partial adsorption layer of a first metal on the surface. Any sites that have already adsorbed with the first metal of the precursor will become unavailable for further adsorption with a subsequent precursor. Alternatively, some sites that have become adsorbed with the first metal of the first precursor may be displaced with a second metal of a second precursor that is adsorbed at the site. To complete the first half reaction, a second precursor may be pulsed onto a surface of the article 205 for a period of time sufficient to allow a second metal of the second precursor to (partially or fully) adsorb onto available sites on the surface (and possibly to displace the first metal of the first precursor), forming a co-deposition adsorption layer on the surface.

A co-deposition cycle of an ALD process starts with a first precursor (i.e., a chemical A or a mixture of chemicals A and B) being flooded into an ALD chamber and partially (or fully) adsorbed onto surfaces of the article (including surfaces of holes and features within the articles). A second precursor (i.e., a chemical B) may be flooded into the ALD chamber and adsorbed onto remaining exposed surfaces of the article. The excess precursor may then be flushed out/purged (i.e., with an inert gas) of the ALD chamber before a reactant (i.e., a chemical R) is introduced into the ALD chamber and subsequently flushed out. Alternatively, or additionally, the chamber may be purged during the first half reaction between deposition of the first precursor and the second precursor. For ALD, the final thickness of material is dependent on the number of reaction cycles that are run because each reaction cycle will grow a layer of a certain thickness that may be one atomic layer or a fraction of an atomic layer.

Aside from being a conformal process, ALD is also a uniform process and is capable of forming very thin films, for example, having a thickness of about 3 nm or more. All exposed surfaces of the article will have the same or approximately the same amount of material deposited. The ALD technique can deposit a thin layer of material at a relatively low temperature (e.g., about 25° C. to about 350° C.) so that it does not damage or deform any materials of the component. Additionally, the ALD technique, can also deposit a layer of material within complex features (e.g., high aspect ratio features) of the component. Furthermore, the ALD technique generally produces relatively thin (i.e., 1 μm or less) coatings that are porosity-free (i.e., pin-hole free), which may eliminate crack formation during deposition.

The complex metal fluoride coating or rare earth metal containing fluoride coating may be grown or deposited using ALD with a first metal containing precursor (e.g., a rare earth metal containing precursor, a tantalum containing precursor, etc.), a second metal containing precursor and a reactant containing fluorine, for example, hydrogen fluoride or other fluorine-containing material. In some embodiments, the first metal containing precursor may contain yttrium, erbium, lanthanum, lutetium, scandium, gadolinium, samarium, dysprosium or tantalum.

In embodiments, the first metal containing precursor and the second metal containing precursor (and in the case of complex metal coatings, the third metal containing precursor, and the fourth metal containing precursor, etc.) are independently selected from a yttrium containing precursor, for example, tris(N,N-bis(trimethylsilyl)amide)yttrium (III), yttrium (III)butoxide, or a yttrium cyclopentadienyl compound (e.g., such as tris(cyclopentadienyl)yttrium(Cp₃Y), tris(methylcyclopentadienyl)yttrium ((CpMe)₃Y)), tris(butylcyclopentadienyl)yttrium, tris(cyclopentadienyl)yttrium, or tris(ethylcyclopentadienyl)yttrum)). Other yttrium containing precursors that may be used include yttrium containing amide-based compounds (e.g., Tris(N,N′-di-i-propylformamidinato)yttrium, tris(2,2,6,6-tetramethyl-heptane-3,5-dionate)yttrium, or tris(bis(trimethylsilyl)amido)lanthanum) and yttrium containing beta-diketonate-based compounds. In some embodiments, the rare earth metal containing fluoride precursor may include erbium. Erbium containing precursors include, but are not limited to, erbium containing cyclopentadienyl compounds, erbium containing amide-based compounds and erbium containing beta-diketonate-based compounds. Example erbium containing precursors include tris-methylcyclopentadienyl erbium(III) (Er(MeCp)₃), erbium boranamide (Er(BA)₃), Er(TMHD)₃, erbium(III)tris(2,2,6,6-tetramethyl-3,5-heptanedionate) and tris(butylcyclopentadienyl) erbium(III) for ALD. Zirconium containing precursors can include, but are not limited to, zirconium containing cyclopentadienyl compounds, zirconium containing amide-based compounds and zirconium containing beta-diketonate-based compounds. Example zirconium containing precursors include zirconium (IV) bromide, zirconium (IV) chloride, zirconium (IV) tert-butoxide, tetrakis(diethylamido)zirconium (IV), tetrakis(dimethylamido)zirconium (IV), tetrakis(ethylmethylamido)zirconium (IV), or a zirconium cyclopentadienyl compound for ALD. Some example zirconium containing precursors include tetrakis(dimethylamido)zirconium, tetrakis(diethylamido)zirconium, tetrakis(N,N′-dimethyl-formamidinate)zirconium, tetra(ethylmethylamido)hafnium, pentakis(dimethylamido)tantalum, and tris(2,2,6,6-tetramethyl-heptane-3,5-dionate)erbium.

In some embodiments, the first metal containing precursor and the second metal containing precursors may be independently selected from a cyclopentadienyl-based precursor, tris(methylcyclopentadienyl)yttrium ((CH₃Cp)₃Y), tris(butylcyclopentadienyl)yttrium, tris(cyclopentadienyl)yttrium, tris(ethylcyclopentadienyl)yttrum, an amidinate-based precursor, Tris(N,N′-di-i-propylformamidinato)yttrium, tris(2,2,6,6-tetramethyl-heptane-3,5-dionate)yttrium, tris(bis(trimethylsilyl)amido)lanthanum, an amide-based precursor and a betadiketonate-based precursor.

In some embodiments, a mixture of two precursors is introduced (i.e., co-dosed) together, where the mixture includes a first percentage of a first metal containing precursor and a second percentage of a second metal containing precursor. For example, the mixture of precursors may include about 1 wt % to about 90 wt %, or about 5 wt % to about 80 wt % or about 20 wt % to about 60 wt % of a first metal containing precursor and about 1 wt % to about 90 wt %, or about 5 wt % to about 80 wt % or about 20 wt % to about 60 wt % of a second metal containing precursor. The mixture may include a ratio of the first metal (e.g., yttrium, tantalum, etc.) containing precursor to the second metal containing precursor that is suitable to form a target type of fluoride material. The atomic ratio of the first metal (e.g., yttrium, tantalum, etc.) containing precursor to the second metal containing precursor may be about 200:1 to about 1:200, or about 100:1 to about 1:100, or about 50:1 to about 1:50, or about 25:1 to about 1:25, or about 10:1 to about 1:10, or about 5:1 to about 1:5.

In one embodiment, a complex metal fluoride coating or rare earth metal containing fluoride coating is co-deposited on a surface of an article using atomic layer deposition. Co-depositing the rare earth metal containing fluoride coating may include contacting the surface with a first metal containing precursor (e.g., a rare earth metal containing precursor) for a first duration to form a partial metal adsorption layer. The first metal containing precursor can be one of a rare earth metal containing precursor, a zirconium containing precursor, a tantalum containing precursor, a hafnium containing precursor or an aluminum containing precursor. Subsequently, the partial metal adsorption layer is contacted with a second metal containing precursor different from the first metal containing precursor for a second duration to form a co-adsorption layer containing the first metal and the second metal. The second metal containing precursor may be at least one of a rare earth metal containing precursor, a zirconium containing precursor, a hafnium containing precursor, a tantalum containing precursor containing precursor or an aluminum containing precursor. Thereafter, the co-adsorption layer is contacted with a fluorine source reactant to form the rare earth metal containing fluoride coating. In certain embodiments, the coating may contain about 1 mol % to about 40 mol %, or about 5 mol % to about 30 mol % of a rare earth metal or tantalum and about 1 mol % to about 40 mol %, or about 1 mol % to about 20 mol % of a second metal. Additionally, the rare earth metal containing fluoride coating can contain a homogenous mixture of the first metal and the second metal.

Referring to FIG. 2A, described is a first metal (M1)—second metal (M2) co-deposition scheme 200 for depositing a rare earth metal containing fluoride coating on an article 205. Article 205 may be introduced to a first metal containing precursor 210 (e.g., a rare earth metal containing precursor) for a duration until a surface of article 205 is partially adsorbed with the first metal containing precursor 210 to form a partial metal adsorption layer 215. Subsequently, article 205 may be introduced to a second metal containing precursor 220 for a duration until the remaining exposed surfaces of the article are adsorbed with the second metal containing precursor 220 to form a co-adsorption layer 225 containing the first metal and the second metal. The first metal containing precursor exposed to an uncoated surface (i.e., with all adsorption sites available) may more efficiently adsorb onto the surface than a second metal containing precursor that is exposed to the partially adsorbed surface. Therefore, co-adsorption layer 225 may be first metal-rich, that is, may contain a higher atomic concentration of the first metal than the second metal. Next, article 205 may be introduced to a reactant 230 for a duration to react with the co-adsorption layer 225 to grow a solid fluoride layer (e.g., YxZr_{y}F_{z} or a YF₃—Zr solid solution) of a rare earth metal containing fluoride coating 235 according to embodiments described herein. The precursors may be any of the precursors as set forth above. The co-deposition of the first metal and the second metal together with the introduction of the reactant is referred to as a M1-M2 co-deposition cycle. The M1-M2 co-deposition cycle can be repeated m times until a desired thickness of the coating is achieved.

Referring to FIG. 2B, described is a M2-M1 co-deposition scheme 202 for depositing a rare earth metal containing fluoride coating on an article 205. Article 205 may be introduced to a second metal containing precursor 220 for a duration until a surface of article 205 is partially adsorbed with the second metal containing precursor 220 to form a partial second metal adsorption layer 216. Subsequently, article 205 may be introduced to a first metal containing precursor 210 for a duration until the remaining exposed surfaces of the article are adsorbed with the first metal containing precursor 220 to form a co-adsorption layer 226. Co-adsorption layer 226 may be second metal rich. Next, article 205 may be introduced to a first reactant 230 to react with the co-adsorption layer 225 to grow a solid layer (e.g., YZrF) of a rare earth metal containing fluoride coating 236 according to embodiments described herein. The precursors may be any of the precursors as set forth above. The co-deposition of the second metal and the first metal together with the introduction of the reactant is referred to as a M2-M1 co-deposition cycle. The M2-M1 co-deposition cycle can be repeated n times until a desired thickness of the coating is achieved.

Each layer of the rare earth metal containing fluoride coating 235, 236 may be uniform, continuous and conformal. The rare earth metal containing fluoride coatings 235, 236 may be porosity free (e.g., have a porosity of 0) or have an approximately 0 porosity in embodiments (e.g., a porosity of 0% to 0.01%). Each layer of the rare earth metal containing fluoride coating 235, 236 may have a thickness of less than one atomic layer to a few atoms in some embodiments after a single ALD deposition cycle. Some metalorganic precursor molecules are large. After reacting with the reactant, large organic ligands may be gone, leaving much smaller metal atoms. One full ALD cycle (e.g., that includes introduction of the precursors followed by introduction of the reactant) may result in less than a single atomic layer. Co-deposition scheme 200 may include repeating m co-deposition cycles to reach a target thickness for the coating 235. Similarly, co-deposition scheme 202 may include repeating n co-deposition cycles to reach a target thickness for the coating 236. M an N may be positive integer values.

The relative concentrations of the first metal (e.g., a rare earth metal, Ta, etc.) and the second metal may be controlled by the type of precursors used, by the temperature of the ALD chamber during adsorption of the precursors onto the surface of the article, the amount of time that the particular precursors remain in the ALD chamber, and the partial pressures of the precursors. For example, use of a tris(N,N-bis(trimethylsilyl)amide)yttrium (III) precursor may result in a lower atomic % of yttria than use of a yttrium cyclopentadienyl precursor.

In some embodiments, more than two types of metal precursors are adsorbed onto the surface of the article 205 in a single co-deposition cycle. For example, a co-deposition cycle may include adsorption of a yttrium precursor onto the surface, followed by adsorption of a zirconium precursor onto the surface, followed by adsorption of a hafnium precursor onto the surface. Each subsequent precursor may adsorb a lower amount of an associated metal onto the surface. Accordingly, the order in which the respective precursors are adsorbed onto the surface to create the co-adsorption layer can be selected to achieve a target ratio of the two or more different metals. An example additional co-deposition scheme that may be performed include a M1-M2-M3 co-deposition scheme in which a first metal (M1) is adsorbed onto the surface, followed by a second metal (M2) being adsorbed onto the surface, followed by a third metal (M3) being adsorbed onto the surface, followed by introduction of a fluorine source reactant. Another example co-deposition scheme that may be performed includes a M2-M1-M3 co-deposition scheme in which the second metal (M2) is adsorbed onto the surface, followed by the first metal (M1) being adsorbed onto the surface, followed by the third metal (M3) being adsorbed onto the surface, followed by introduction of an fluorine source reactant. Another example co-deposition scheme that may be performed includes a M3-M1-M2 co-deposition scheme in which the third metal (M3) is adsorbed onto the surface, followed by the first metal (M1) being adsorbed onto the surface, followed by the second metal (M2) being adsorbed onto the surface, followed by introduction of a fluorine source reactant. Another example co-deposition scheme that may be performed includes a M3-M2-M1 co-deposition scheme in which the third metal (M3) is adsorbed onto the surface, followed by the second metal (M2) being adsorbed onto the surface, followed by the first metal (M1) being adsorbed onto the surface, followed by introduction of a fluorine source reactant. Greater numbers of precursors may also be adsorbed onto the surface to create more complex metal fluorides. The greater the number of metals used, the greater the number of possible permutations that are possible.

With reference to FIG. 2C, in some embodiments, a multi-layer stack may be deposited on article 205 using a co-deposition ALD process 203. An optional buffer layer 209 as described above may be deposited onto article 205. In an example where the buffer layer 209 is alumina (Al₂O₃), in a first half reaction, article 205 (e.g., an Al 6061 substrate) may be introduced to an aluminum containing precursor (e.g., trimethyl aluminum (TMA)) (not shown) for a duration until all of the reactive sites on the surface are consumed. The remaining alumina containing precursor may be flushed out of the reaction chamber and then a reactant (not shown) of H₂O or another oxygen source may be injected into the reactor to start the second half cycle. A buffer layer 209 of Al₂O₃ may be formed after H₂O molecules react with the Al containing adsorption layer created by the first half reaction.

Buffer layer 209 may be uniform, continuous and conformal. The buffer layer 209 may be porosity free (e.g., have a porosity of 0) or have an approximately 0 porosity in embodiments (e.g., a porosity of 0% to 0.01%). Multiple full ALD deposition cycles may be implemented to deposit a buffer layer 209 having a target thickness, with each full cycle (e.g., including introducing the aluminum containing precursor, flushing, introducing H₂O reactant, and again flushing) adding to the thickness by an additional fraction of an atom to a few atoms. In embodiments, buffer layer 209 may have a thickness of about 10 nm to about 1.5 μm, or about 10 nm to about 15 nm, or about 0.8 μm to about 1.2 μm.

Subsequently, a M1-M2 co-deposition cycle in accordance with the description above relating to FIG. 2A or a M2-M1 co-deposition cycle in accordance with the description relating to FIG. 2B may be performed on article 205 having the optional buffer layer 209. The buffer layer 209, rather than the surface of the article or the body of the article, would be partially adsorbed with the first metal containing precursor 210 or second precursor 220 to form partial adsorption layer 215. Thereafter, the precursors may be flushed from the ALD chamber using an inert gas (e.g., nitrogen) and then a M1-M2 co-deposition cycle in accordance with the description above relating to FIG. 2B, or a M2-M1 co-deposition cycle in accordance with the description above relating to FIG. 2A, may be performed on article 205 having the optional buffer layer 209 and M1-M2 coating layer 235.

The rare earth metal containing fluoride layer resulting from the M1-M2 co-deposition cycle may contain a first percentage of the first metal and a second percentage of the second metal. The M2-M1 co-deposition cycle results in an additional layer containing a third percentage of the first metal and a fourth percentage of the second metal. In embodiments, the third percentage may be lower than the first percentage and the fourth percentage may be higher than the third percentage. Thus, using the two co-deposition cycles, a multilayer coating having buffer layer 209, M1-M2 layer 235 and M2-M1 layer 236 can be formed. As before, either or both of the co-deposition cycles can be repeated m or n number of times, where m and n are each integers greater than zero and represent the number of co-deposition cycles. In some embodiments, the ratio of m ton can be 1:50 to about 50:1, or about 1:25 to about 25:1, or about 1:10 to about 10:1, or about 1:2 to about 2:1, or 1:1. The co-deposition cycles can be performed consecutively and/or in an alternating manner to build the coating. The alternating layers 235 and 236 described with respect to FIG. 2C were formed by the co-deposition cycles in a 1:1 manner, where there is a single layer of a M1-M2 coating layer for each single layer of a M2-M1 coating layer. However, in other embodiments there may be other patterns. For example, two M1-M2 co-deposition cycles may be followed by one M2-M1 co-deposition cycle (2:1) and then this sequence may be repeated again.

According to various embodiments, the M1-M2 co-deposition cycle can be represented as m*(M1+M2+F), where m is an integer greater than zero and represents the number of M1-M2 co-deposition cycles, M1 represents the amount (in mol %) of first metal (e.g., yttrium) deposited, M2 represents the amount (mol %) of the second metal deposited and F represents the amount (mol %) of fluorine deposited. The M2-M1 co-deposition cycle can be represented as n*(M2+M1+F), where n is an integer greater than zero and represents the number of M2-M1 co-deposition cycles, M2 represents the amount (mol %) of the second metal deposited, M1 represents the amount (mol %) of first metal (e.g., yttrium) deposited and F represents the amount (mol %) of fluorine deposited.

As shown in FIG. 2C, the following formula may be used to achieve a target composition of the rare earth metal containing fluoride coating: K*[m*(M1+M2+O)+n*(M2+M1+O)] where K is an integer greater than zero and represents a number of super-cycles that are performed to achieve a target thickness. By adjusting K, m and n, regardless of the chemical properties of the precursor, one can achieve a desired composition (e.g., a desired ratio of first metal to the second metal) in the coating.

FIG. 2C illustrates co-deposition using two different metals. However, in further embodiments co-deposition may be performed with more than two metals, as described above. If more than two different metals are used, then there are more than two different co-deposition sequences that may be performed. For example, for a three metal co-deposition the following co-deposition schemes may be intermixed to achieve a coating with a target composition: M1+M2+M3+F, M1+M3+M2+F, M2+M1+M3+F, M2+M3+M1+F, M3+M1+M2+F, M3+M2+M1+F. Accordingly, the following formula may be used to achieve a target composition K*[a*(M1+M2+M3+F)+b*(M1+M3+M2+F)+c*(M2+M1+M3+F)+d*(M2+M3+M1+F)+e*(M3+M1+M2+F)+f*(M3+M2+M1+F)], where a, b, c, d, e and f are non-negative integers. The mol % of each of M1, M2 and M3 for each co-deposition scheme may be determined through experimentation. Similarly, for a four metal co-deposition the following co-deposition schemes may be intermixed to achieve a coating with a target composition: M1+M2+M3+M4+F, M1+M3+M4+M2+F, M1+M4+M2+M3+F, M1+M3+M2+M4+F, M1+M4+M3+M2+F, M1+M2+M4+M3+F, M2+M1+M3+M4+F, M2+M3+M4+M1+F, M2+M4+M1+M3+F, M2+M1+M4+M3+F, M2+M3+M1+M4+F, M2+M4+M3+M1+F, M3+M1+M2+M4+F, M3+M2+M4+M1+F, M3+M4+M1+M2+F, M3+M1+M4+M2+F, M3+M2+M1+M4+F, M3+M4+M2+M1+F, M4+M1+M2+M3+F, M4+M2+M3+M1+F, M4+M3+M1+M2+F, M4+M1+M3+M2+F, M4+M2+M1+M3+F, M4+M3+M3+M1+F. Accordingly, the following formula may be used to achieve a target composition K[a*(M1+M2+M3+M4+F)+b*(M1+M3+M4+M2+F)+c*(M1+M4+M2+M3+F)+d*(M1+M3+M2+M4+F)+e*(M1+M4+M3+M2+F)+f*(M11+M2+M4+M3+F)+g*(M2+M1+M3+M4+F)+h* (M2+M3+M4+M1+F)+i*(M2+M4+M1+M3+F)+j*(M2+M1+M4+M3+F)+k(M2+M3+M1+M4+F)+l*(M2+M4+M3+M1+F)+m*(M3+M1+M2+M4+F)+n*(M3+M2+M4+M1+F)+o*(M3+M4+M1+M2+F)+p*(M3+M1+M4+M2+F)+q*(M3+M2+M1+M4+F)+r*(M3+M4+M2+M1+F)+s* (M4+M1+M2+M3+F)+t*(M4+M2+M3+M1+F)+u*(M4+M3+M1+M2+F)+v*(M4+M1+M3+M2+F)+w*(M4+M2+M1+M3+F)+x*(M4+M3+M3+M1+F)], where a through x are non-negative integers.

A dose time ratio may be expressed as the ratio of the first metal (e.g., yttrium) precursor exposure time to the second metal precursor exposure time. It should be noted that the dose time and ratio of precursor materials are controllable whereas adhesion of the precursors to the surface, sticking coefficient and chemical interaction may not be. The pressure of the ALD chamber and the temperature also affect the adsorption of the precursors on the surface. For example, the reactivity of Zr is slightly higher than Y and so a resulting coating with a mixture of zirconium and yttrium may be zirconium-rich. Under equilibrium conditions in the chamber, the dose times can be adjusted to achieve a desired composition. At equilibrium, the composition is limited by the chemical reactivity of the precursors and the sticking coefficient of the materials. In some embodiments, there is no purge between the introduction of the first metal containing precursor and the second metal containing precursor because this could affect adsorption of the materials onto the article.

In embodiments, a ratio of a first number of M1-M2 co-deposition cycles and a second number of M2-M1 co-deposition cycles may be selected to result in a target first mol % of the first metal and a target second mol % of the second metal. Furthermore, a plurality of deposition super-cycles may be performed, where each deposition super-cycle includes performing the first number of M1-M2 co-deposition cycles and performing the second number of M2-M1 deposition cycles.

A ratio of the first metal containing fluoride layer thickness to the buffer layer thickness may be 200:1 to 1:200, or about 100:1 to 1:100, or about 50:1 to about 1:50. A higher ratio of the first metal containing fluoride layer thickness to the buffer layer thickness (e.g., 200:1, 100:1, 50:1, 20:1, 10:1, 5:1, 2:1 etc.) may provide better corrosion and erosion resistance, while a lower ratio of the first metal-containing fluoride layer thickness to the buffer layer thickness (e.g., 1:2, 1:5, 1:10, 1:20, 1:50, 1:100, 1:200) may provide better heat resistance (e.g., improved resistance to cracking and/or delamination caused by thermal cycling). The thickness ratio may be selected in accordance with specific chamber applications. In an example, for a capacitive coupled plasma environment with high sputter rate, a top layer of 1 μm may be deposited on a 50 nm buffer Al₂O₃ layer. For a high temperature chemical or radical environment without energetic ion bombardment, a top layer of 100 nm with a bottom layer of 500 nm may be optimal.

Referring to FIG. 2D, an article 205 may be inserted into an ALD chamber. In this embodiment, the co-deposition process involves co-dosing at least two precursors simultaneously onto the surface of the article. Article 205 may be introduced to a mixture of precursors 210, 220 for a duration until a surface of the article or a body of the article is fully adsorbed with the mixture of precursors 210, 220 to form co-adsorption layer 227. The mixture of two precursors A and B, such as a yttrium-containing precursor and another rare earth metal fluoride precursor, are co-injected (AₓB_{y}) at any number of ratios, for example, A90+B10, A70+B30, A50+B50, A30+B70, A10+A90 and so on, into the chamber and adsorbed on the surface of the article. In these examples, x and y are expressed in atomic ratios (mol %) for Ax+By. For example A90+B10 is 90 mol % of A and 10 mol % of B. In some embodiments, at least two precursors are used, in other embodiments at least three precursors are used and in yet further embodiments at least four precursors are used. Subsequently, article 205 having co-adsorption layer 227 may be introduced to a reactant 230 to react with co-adsorption layer 227 to grow a solid rare earth metal containing fluoride coating 235. As shown, the co-deposition by co-dosing of the rare earth metal containing coating 235 may be repeated m times to achieve a desired coating thickness, where m is an integer value greater than 1.

ALD processes may be conducted at various temperatures depending on the type of process. The optimal temperature range for a particular ALD process is referred to as the “ALD temperature window.” Temperatures below the ALD temperature window may result in poor growth rates and non-ALD type deposition. Temperatures above the ALD temperature window may result in reactions taken place via a chemical vapor deposition (CVD) mechanism. The ALD temperature window may range from about 100° C. to about 650° C. In some embodiments, the ALD temperature window is from about 20° C. to about 200° C., or about 25° C. to about 150° C., or about 100° C. to about 120° C., or about 20° C. to 125° C.

The ALD process allows for a conformal rare earth metal containing fluoride coating having uniform thickness on articles and surfaces having complex geometric shapes, holes with high aspect ratios (e.g., pores), and three-dimensional structures. Sufficient exposure time of each precursor to the surface enables the precursor to disperse and fully react with the surface in its entirety, including all of its three-dimensional complex features. The exposure time utilized to obtain conformal ALD in high aspect ratio structures is proportionate to the square of the aspect ratio and can be predicted using modeling techniques. Additionally, the ALD technique is advantageous over other commonly used coating techniques because it allows in-situ on demand material synthesis of a particular composition or formulation without the need for a lengthy and difficult fabrication of source materials (such as powder feedstock and sintered targets.

Another possible ALD deposition technique involves the sequential deposition of multiple different metal fluoride layers, followed by interdiffusion between the layers. This may include introducing a first precursor for a first metal, and then introducing a first reactant to form a first metal fluoride layer. Subsequently a second precursor for a second metal may be introduced, followed by the first reactant or a second reactant to form a second metal fluoride layer. An annealing operation may then be performed in some embodiments.

In some embodiments, two or more of the above described ALD deposition techniques may be combined to produce a homogenous metal fluoride coating. For example, do-deposition and co-dosing may be combined, co-deposition and sequential deposition may be combined, and/or co-dosing and sequential deposition may be combined. In an example, a mixture of a yttrium precursor and an erbium precursor may be injected into an ALD chamber to adsorb yttrium and erbium onto a surface of an article. Subsequently, a mixture of a zirconium precursor and a hafnium precursor may be injected into the ALD chamber to further adsorb zirconium and hafnium onto the surface. Subsequently, a fluorine source reactant may be injected into the ALD chamber to form a YᵥEr_{w}ZrₓHf_{y}F_{z} coating.

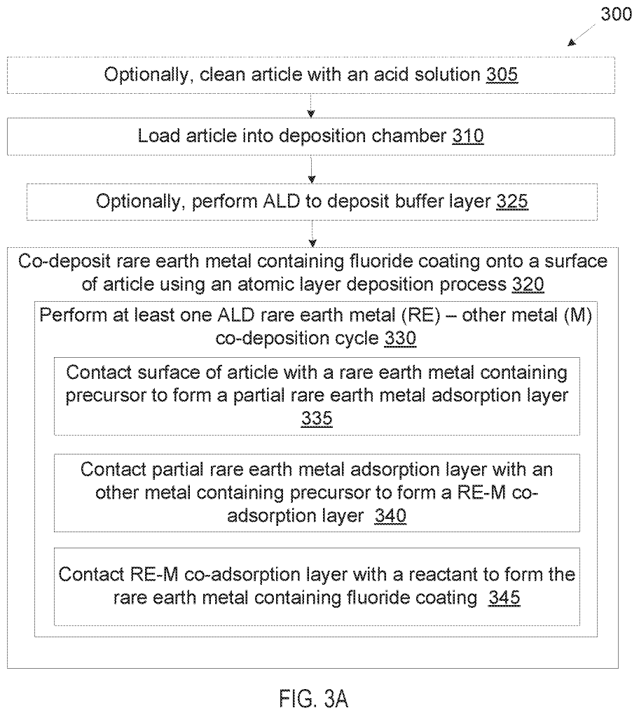

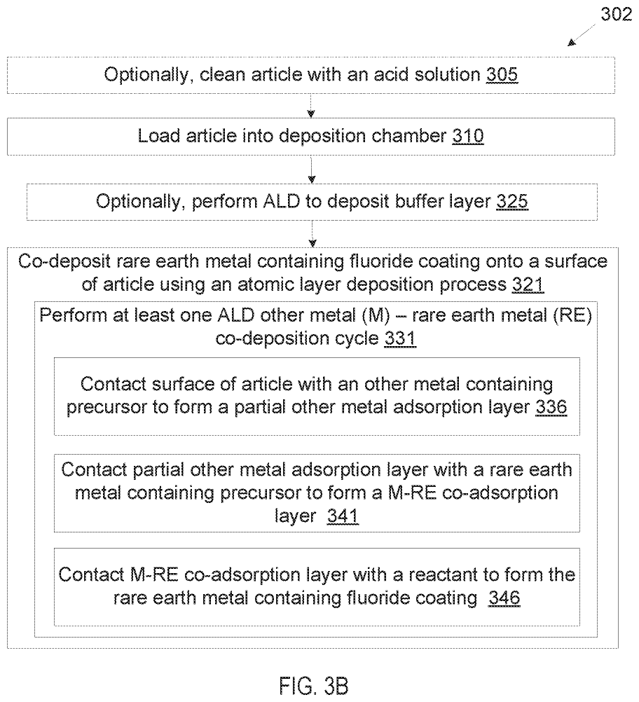

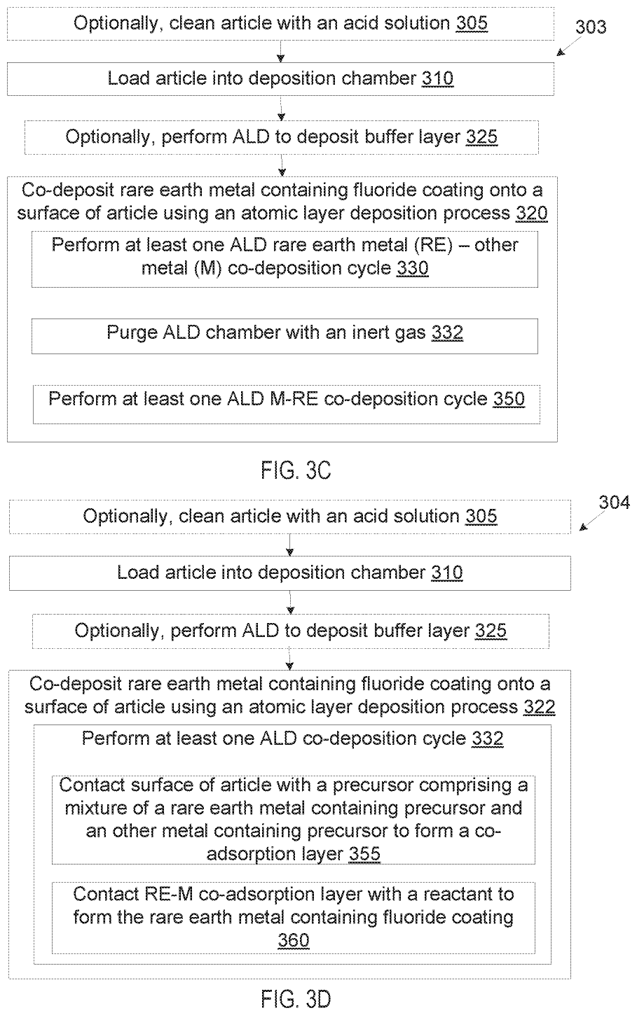

FIG. 3A illustrates a method 300 for forming a rare earth metal containing fluoride coating by a co-deposition ALD process. Method 300 may be used to coat any articles described herein. The method 300 may optionally begin by selecting precursors for forming the coating. The composition selection and method of forming may be performed by the same entity or by multiple entities.

The method 300 may optionally include, at block 305, cleaning the article with an acid solution. In one embodiment, the article is bathed in a bath of the acid solution. The acid solution may be a hydrofluoric acid (HF) solution, a hydrochloric acid (HCl) solution, a nitric acid (HNO₃) solution, or combination thereof in embodiments. The acid solution may remove surface contaminants from the article and/or may remove an oxide from the surface of the article. Cleaning the article with the acid solution may improve a quality of a coating deposited using ALD. In one embodiment, an acid solution containing approximately 0.1-5.0 vol % HF is used to clean chamber components made of quartz. In one embodiment, an acid solution containing approximately 0.1-20 vol % HCl is used to clean articles made of Al₂O₃. In one embodiment, an acid solution containing approximately 5-15 vol % HNO₃ is used to clean articles made of aluminum and additional metals.

At block 310, the article is loaded into an ALD deposition chamber. At block 325, the method 300 includes optionally depositing a buffer layer on a surface of the article or a body of the article using ALD. At block 320, ALD is performed to co-deposit a rare earth metal containing fluoride coating on the article. At least one M1-M2 co-deposition cycle 330 is performed. The M1-M2 co-deposition cycle includes, at block 335, introducing a first metal containing precursor into the ALD chamber containing the article (with or without the buffer layer). The first metal containing precursor contacts the surface of the article or a body of the article to form a partial metal adsorption layer. At block 340, a second metal containing precursor is introduced into the ALD chamber containing the article having the partial metal adsorption layer. The second metal containing precursor contacts the remaining exposed surfaces of the article or a body of the article to form a M1-M2 co-adsorption layer. At block 345, a reactant is introduced into the ALD chamber and reacts with the M1-M2 co-adsorption layer to form the rare earth metal containing fluoride coating.

FIG. 3B illustrates a method 302 of forming a rare earth metal containing fluoride coating by a co-deposition ALD process. Method 302 may be used to coat any articles described herein. The method 302 may optionally begin by selecting precursors for forming the coating. The composition selection and method of forming may be performed by the same entity or by multiple entities.

The method 302 may optionally include, at block 305, cleaning the article with an acid solution. At block 310, the article is loaded into an ALD deposition chamber. At block 325, the method 302 includes optionally depositing a buffer layer on a surface of the article or a body of the article using ALD. At block 321, ALD is performed to co-deposit a rare earth metal containing fluoride coating on the article. At least one M2-M1 co-deposition cycle 331 is performed. The M2-M1 co-deposition cycle includes, at block 336, introducing a second metal containing precursor into the ALD chamber containing the article (with or without the buffer layer). The second metal containing precursor contacts the surface of the article or a body of the article to form a partial metal containing adsorption layer. At block 341, a first metal containing precursor is introduced into the ALD chamber containing the article having the second metal adsorption layer. The first metal containing precursor contacts the remaining exposed surfaces of the article or a body of the article to form a M2-M1 co-adsorption layer. At block 346, a reactant is introduced into the ALD chamber and reacts with the M2-M1 co-adsorption layer to form the rare earth metal containing fluoride coating.

FIG. 3C illustrates a combined method 303 of forming a multilayer coating as described herein which includes performing at least one M1-M2 co-deposition cycle at block 330. Subsequently, the ALD chamber is purged with an inert gas at block 332. At block 350, at least one M2-M1 co-deposition cycle is performed to form the rare earth metal containing fluoride coating. As discussed above the co-deposition cycles may be repeated any number of times and in any order to achieve a desired composition of the rare earth metal containing coating. Although not shown, in some embodiments, the deposited coating may be annealed. An annealing temperature of up to about 500° C. may be used for coatings where the second metal is aluminum.

FIG. 3D illustrates a method 304 of co-depositing by co-dosing a rare earth metal containing fluoride coating according to embodiments described herein. The method 304 may optionally include, at block 305, cleaning the article with an acid solution. At block 310, the article is loaded into an ALD deposition chamber. At block 325, the method 302 includes optionally depositing a buffer layer on a surface of the article or a body of the article using ALD.

At block 322, ALD is performed to co-deposit by co-dosing a rare earth metal containing fluoride coating on the article 205. At least one co-deposition cycle 332 is performed. The co-deposition cycle includes, at block 355, introducing a mixture of a first metal containing precursor and a second metal containing precursor into the ALD chamber containing the article (with or without the buffer layer). The first metal containing precursor and the second metal containing precursor may, independently include a metal selected from a rare earth metal, zirconium, aluminum, hafnium and tantalum. The mixture of precursors contacts the surface of the article or a body of the article to form a co-adsorption layer. At block 360, a reactant is introduced into the ALD chamber and reacts with the co-adsorption layer to form the rare earth metal containing fluoride coating. The co-deposition cycle may be repeated as many times as is necessary to achieve a desired thickness of the coating.

According to embodiments, methods can include co-depositing a rare earth metal containing fluoride coating on a surface of an article using atomic layer deposition. Co-depositing the rare earth metal containing fluoride coating can include contacting the surface with a first precursor for a first duration to form a partial first metal adsorption layer, wherein the first precursor is selected from a rare earth metal containing precursor, a zirconium containing precursor, a hafnium containing precursor, a tantalum containing precursor or an aluminum containing precursor; contacting the partial metal adsorption layer with a second precursor different from the first precursor for a second duration to form a co-adsorption layer comprising the first metal and the second metal, wherein the second precursor is selected from a rare earth metal containing precursor, a zirconium containing precursor, a hafnium containing precursor, a tantalum containing precursor or an aluminum containing precursor; and contacting the co-adsorption layer with a reactant to form the rare earth metal containing fluoride coating. In certain embodiments, the rare earth metal containing fluoride coating comprises about 1 mol % to about 40 mol % of the first metal and about 1 mol % to about 40 mol % of the second metal, and the rare earth metal containing fluoride coating can be a homogenous mixture of the first metal and the second metal.

According to embodiments, co-depositing the rare earth metal containing fluoride coating includes performing at least one M1-M2 co-deposition cycle, including contacting the surface with the first metal containing precursor to form the partial first metal adsorption layer; subsequently contacting the partial first metal adsorption layer with the second metal containing precursor to form a M1-M2 co-adsorption layer; and contacting the M1-M2 co-adsorption layer with the reactant. The at least one M1-M2 co-deposition cycle can result in a layer containing a first percentage of the first metal and a second percentage of the second metal.

In embodiments, co-depositing the rare earth metal containing fluoride coating can further include performing at least one M2-M1 co-deposition cycle including contacting the surface with the second metal containing precursor to form a partial second metal adsorption layer; subsequently contacting the partial metal adsorption layer with the rare earth metal containing precursor to form a M2-M1 co-adsorption layer; and contacting the M2-M1 co-adsorption layer with the reactant. The at least one M2-M1 co-deposition cycle can result in an additional layer comprising a third percentage of the first metal and a fourth percentage of the second metal, wherein the third percentage is lower than the first percentage and the fourth percentage is greater than the second percentage.

Methods according to embodiments described herein can further include selecting a ratio of a first number of M1-M2 co-deposition cycles and a second number of M2-M1 co-deposition cycles that results in a target first mol % of the first metal and a target second mol % of the second metal; and performing a plurality of deposition super-cycles, wherein each deposition super-cycle comprises performing the first number of M1-M2 co-deposition cycles and performing the second number of M2-M1 deposition cycles. According to embodiments, performing the at least one M1-M2 co-deposition cycle, can include contacting the surface with the rare earth metal containing precursor for about 50 milliseconds to about 60 seconds, or about 1 second to about 60 seconds, or about 5 seconds to about 60 seconds, or about 10 seconds to about 60 seconds; contacting the partial first metal adsorption layer with the second metal containing precursor for about about 50 milliseconds to about 60 seconds, or about 1 second to about 60 seconds, or about 5 seconds to about 60 seconds, or about 10 seconds to about 60 seconds; and contacting the M1-2 co-adsorption layer with the reactant for about 50 milliseconds to about 60 seconds, or about 1 second to about 60 seconds, or about 5 seconds to about 60 seconds, or about 10 seconds to about 60 seconds; and performing the at least one M2-M1 co-deposition cycle. Performing the at least one M2-M1 co-deposition cycle can include contacting the surface with the second metal containing precursor for about 50 milliseconds to about 60 seconds, or about 1 second to about 60 seconds, or about 5 seconds to about 60 seconds, or about 10 seconds to about 60 seconds; contacting the partial metal adsorption layer with the rare earth metal containing precursor for about 50 milliseconds to about 60 seconds, or about 1 second to about 60 seconds, or about 5 seconds to about 60 seconds, or about 10 seconds to about 60 seconds; and contacting the M2-M1 co-adsorption layer with the reactant for about 50 milliseconds to about 60 seconds, or about 1 second to about 60 seconds, or about 5 seconds to about 60 seconds, or about 10 seconds to about 60 seconds.

The following examples are set forth to assist in understanding the embodiments described herein and should not be construed as specifically limiting the embodiments described and claimed herein. Such variations, including the substitution of all equivalents now known or later developed, which would be within the purview of those skilled in the art, and changes in formulation or minor changes in experimental design, are to be considered to fall within the scope of the embodiments incorporated herein. These examples may be achieved by performing methods described herein.

### EXAMPLE 1—EFFECT OF FLUORINE ON A Y₂O₃ COATING

A yttrium oxide coating was deposited on a chamber component using atomic layer deposition. The coated substrate was subjected to 3,000 cycles of nitrogen trifluoride (NF₃) plasma in a chemical vapor deposition chamber at a temperature of 450° C. A cross sectional side view transmission electron microscopy (TEM) image of the Y₂O₃ coating on the substrate was obtained. A transmission electron microscopy energy-dispersive x-ray spectroscopy (TEM/EDS) line scan of the Y₂O₃ coating was also obtained During NF₃ processing of the Y₂O₃ substrate, an uncontrolled fluorine (F) diffusion/reaction into the Y₂O₃, damaged the coating and the underlying substrate. The fluorine (1) caused surface deterioration of the coating; (2) erosion and therefore, particle generation; (3) diffused through the coating; and (4) increased risk of cracking and delamination of the coating.

### EXAMPLE 2—COMPARISON OF Al₂O₃, Y₂O₃ AND YF₃ COATINGS PREPARED BY ALD

Sample coupons having an Al₂O₃, Y₂O₃ or YF₃ coating were prepared using an ALD deposition scheme. The Al₂O₃ coating had a thickness of 500 nm, the Y₂O₃ coating had a thickness of 100 nm and YF₃ coating had a thickness of 100 nm. Each sample was exposed to a CF₄ inductively coupled plasma for 34 RF-hours at a temperature of 75° C. and an RF source power of 300 W.

Following exposure to the CF₄ plasma, while the YF₃ and Y₂O₃ coatings both did not have a reduction in thickness (e.g., etch rate of approximately 0), the YF₃ coating also had no microstructure degradation whereas the Y₂O₃ coating experienced significant microstructure degradation. The Y₂O₃ coating had dense nano-cracks and delamination whereas the YF₃ coating did not have these features. Without being bound by any particular theory, it is believed that when Y₂O₃ coatings are exposed to fluorine plasma, fluorine diffuses into the coating and displaces oxygen molecules, which causes volumetric expansion of the Y₂O₃ coating resulting in nano-cracks and delamination of the coating. Before nano-cracks occur, the Y₂O₃ coating and YF₃ coating act as a diffusion barrier and prevent metals in the coated article from diffusing through the coating and contaminating processed substrates. However, nano-cracks in the Y₂O₃ coating causes the Y₂O₃ coating to no longer act as a diffusion barrier, as the nano-cracks permit metals to diffuse through the coating. Additionally, the nano-cracks cause the Y₂O₃ coating to flake off and generate particle contamination on processed substrates. In contrast, since no nano-cracks are generated in the YF₃ coating, the YF₃ coating remains a good diffusion barrier and does not cause particle contamination even after repeated exposure to fluorine-rich plasma. When fluorine is used in the coating instead of oxygen, while fluorine may diffuse into the YF₃ coating, the YF₃ coating does not experience volumetric expansion and, thus, does not form nano-cracks and does not delaminate. The Al₂O₃ coating experienced significant etching such that the thickness reduced from 500 nm to about 225 nm (i.e., about 275 nm were etched away).

Similar conditions to those shown above with regards to YF₃ and Y₂O₃ have also been demonstrated for other rare earth oxide versus rare earth fluoride comparisons. For example, a comparison of a YₓZr_{y}O_{z} coating and a YₓZr_{y}F_{z} coating exposed to a CF₄ plasma shows that the YₓZr_{y}O_{z} coating experiences nano-cracking (and thus no longer functions as a diffusion barrier and causes particle contamination) while the YₓZr_{y}F_{z} coating does not experience nano-cracking (and thus functions as a diffusion barrier and does not cause particle contamination). The same results also occur for comparisons of other single metal and multi-metal rare earth oxides to single metal and multi-metal rare earth fluorides.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

1. An article comprising:
a body; and
a rare earth metal containing fluoride coating on a surface of the body, wherein the rare earth metal containing fluoride coating as deposited is pin-hole free,
wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, zirconium, hafnium, aluminum and tantalum, wherein the first metal is different from the second metal, and
wherein the rare earth metal containing fluoride coating comprises a homogenous mixture of the first metal and the second metal.

2. The article of claim 1, wherein the rare earth metal containing fluoride coating has a thickness of about 5 nm to about 10 μm.

3. The article of claim 1, wherein the article is a component of a processing chamber selected from a group consisting of a chamber wall, a shower head, a nozzle, a plasma generation unit, a radiofrequency electrode, an electrode housing, a diffuser and a gas line.

4. The article of claim 1, wherein the body comprises a material selected from a group consisting of aluminum, steel, silicon, copper and magnesium.

5. The article of claim 1, wherein the first metal comprises a rare earth metal selected from a group consisting of yttrium, erbium, lanthanum, lutetium, scandium, gadolinium, samarium and dysprosium.

6. The article of claim 1, wherein the first metal comprises yttrium, and wherein the rare earth metal containing fluoride coating comprises zirconium at a concentration of about 1 mol % to about 40 mol %.

7. The article of claim 1, wherein the rare earth metal containing fluoride coating comprises a composition selected from a group consisting of YₓZr_{y}F_{z}, ErₓZr_{y}F_{z}, Y_{w}ZrₓHf_{y}F_{z}, Er_{w}ZrₓHf_{y}F_{z}, YᵥEr_{w}ZrₓHf_{y}F_{z}, YₓHf_{y}F_{z}, ErₓHf_{y}F_{z}, YₓTa_{y}F_{z}, ErₓTa_{y}F_{z}, Y_{w}TaₓHf_{y}F_{z}, Er_{w}TaₓHf_{y}F_{z} and YᵥEr_{w}TaₓHf_{y}F_{z}.

8. The article of claim 1, further comprising a buffer layer on the surface of the body, wherein the rare earth metal containing fluoride coating covers the buffer layer, and wherein the buffer layer comprises a material selected from a group consisting of an aluminum oxide, a silicon oxide and aluminum nitride.

9. A method comprising:
co-depositing a rare earth metal containing fluoride coating on a surface of an article using atomic layer deposition, wherein co-depositing the rare earth metal containing fluoride coating comprises:
contacting the surface with a first metal containing precursor or a second metal containing precursor for a first duration to form a partial metal adsorption layer comprising a first metal (M1) or a second metal (M2), wherein the first metal containing precursor or the second metal containing precursor is selected from a group consisting of a rare earth metal containing precursor, a zirconium containing precursor, a hafnium containing precursor, an aluminum containing precursor and a tantalum containing precursor;
contacting the partial metal adsorption layer with the second metal containing precursor or the first metal containing precursor for a second duration to form a co-adsorption layer comprising the first metal (M1) and the second metal (M2), wherein the first metal is different from the second metal; and
contacting the co-adsorption layer with a reactant to form the rare earth metal containing fluoride coating,
wherein the rare earth metal containing fluoride coating comprises about 1 mol % to about 40 mol % of the first metal and about 1 mol % to about 40 mol % of the second metal, and
wherein the rare earth metal containing fluoride coating comprises a homogenous mixture of the first metal and the second metal.

10. The method of claim 9, wherein co-depositing the rare earth metal containing fluoride-coating comprises:
performing at least one M1-M2 co-deposition cycle, comprising:
contacting the surface with the first metal containing precursor to form the partial metal adsorption layer;
subsequently contacting the partial metal adsorption layer with the second metal containing precursor to form a M1-M2 co-adsorption layer; and
contacting the M1-M2 co-adsorption layer with the reactant,
wherein the at least one M1-M2 co-deposition cycle results in a layer comprising a first percentage of the first metal and a second percentage of the second metal.

11. The method of claim 10, wherein co-depositing the rare earth metal containing fluoride coating further comprises:
performing at least one M2-M1 co-deposition cycle comprising:
contacting the surface with the second metal containing precursor to form a second partial metal adsorption layer;
subsequently contacting the second partial metal adsorption layer with the first metal containing precursor to form a M2-M1 co-adsorption layer; and
contacting the M2-M1 co-adsorption layer with the reactant,
wherein the at least one M2-M1 co-deposition cycle results in an additional layer comprising a third percentage of the first metal and a fourth percentage of the second metal, wherein the third percentage is lower than the first percentage and the fourth percentage is greater than the second percentage.

12-17. (canceled)

18. A method comprising:
co-depositing a rare earth metal containing fluoride coating on a surface of an article using atomic layer deposition, wherein co-depositing the rare earth metal containing fluoride coating comprises:
performing at least one co-dosing cycle comprising:
contacting the surface with a mixture of a first precursor and a second precursor for a first duration to form a co-adsorption layer, wherein the first precursor and the second precursor are each selected from a group consisting of a rare earth metal containing precursor, a zirconium containing precursor, a hafnium containing precursor, an aluminum containing precursor and a tantalum containing precursor; and
contacting the co-adsorption layer with a fluorine containing reactant to form the rare earth metal containing fluoride coating,
wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, zirconium, hafnium, aluminum and tantalum, wherein the first metal is different from the second metal, and
wherein the rare earth metal containing fluoride coating comprises a homogenous mixture of the first metal and the second metal.

19. The method of claim 18, wherein the mixture further comprises a third precursor comprising a metal different from the first metal of the first precursor and the second metal of the second precursor, wherein the metal in the third precursor is selected from a group consisting of yttrium, erbium, lanthanum, lutetium, scandium, gadolinium, samarium, dysprosium, zirconium, hafnium and tantalum, and wherein the homogenous mixture further comprises the metal of the third precursor.

20. A method comprising:
depositing a rare earth metal containing fluoride coating on a surface of an article using atomic layer deposition, wherein depositing the rare earth metal containing fluoride coating comprises:
contacting the surface with a first precursor for a first duration to form a first metal adsorption layer;
contacting the first metal adsorption layer with a fluorine containing reactant to form a first metal fluoride layer,
contacting the first metal layer with a second precursor for a second duration to form a second metal adsorption layer;
contacting the second metal adsorption layer with the fluorine containing reactant or an alternative fluorine containing reactant to form a second metal fluoride layer,
forming the rare earth metal containing fluoride coating from the first metal fluoride layer and the second metal fluoride layer,
wherein the rare earth metal containing fluoride coating comprises about 1 mol % to about 40 mol % of a first metal and about 1 mol % to about 40 mol % of a second metal, wherein the first metal and the second metal are independently selected from a group consisting of a rare earth metal, hafnium and tantalum, wherein the first metal is different from the second metal.

21. The article of claim 1, wherein the rare earth metal containing fluoride coating comprises the product of a co-adsorption layer comprising the first metal and the second metal and a reactant.

22. The article of claim 1, wherein the rare earth metal containing fluoride coating further comprises a third metal different from the first metal and the second metal, wherein the third metal is selected from a group consisting of yttrium, erbium, lanthanum, lutetium, scandium, gadolinium, samarium, dysprosium, zirconium, hafnium and tantalum, and wherein the homogenous mixture further comprises the metal of the third precursor.

23. The article of claim 1, wherein the rare earth metal containing fluoride coating has a thickness of about 5 nm to about 10 μm.

24. The article of claim 1, further comprising a buffer layer.

25. The article of claim 24, wherein the buffer layer has a thickness of about 10 nm to about 1.5 μm.

26. The article of claim 24, wherein the buffer layer comprises a porosity of 0% to 0.01%.
